(19) United States
(12) Patent Application Publication
(10) Pub. No.: US 2004/0243916 A1
(43) Pub. Date: Dec. 2, 2004

(54) Method and apparatus for decoding multi-level trellis coded modulation

(76) Inventors: Sun Young Kim, Daejeon (KR); Si Yeon Choi, Jeonranam-do (KR); Duck Hyun Kim, Kwangju (KR); Kil Nam Oh, Kwangju (KR)

Correspondence Address: J C Patents Inc, 4 Venture Suite 250, Irvine, CA, 92618, US

(21) Appl. No.: 10/484,183

(22) PCT Filed: Aug. 8, 2001
(86) PCT No.: PCT/KR01/01349

(30) Foreign Application Priority Data
Jul. 19, 2001 (KR) 2001/43596

(51) Int. Cl. H03M 13/03

(52) U.S. Cl. 714/796

(57) ABSTRACT

The present invention discloses method and apparatus for decoding multi-level trellis coded modulation having improved efficiency by parallel processing when decodes multi-level trellis coded modulation. The method and apparatus according to the present invention divide branches having the next state periodically using commonness among branches divided from the current state to the next state, and improve efficiency of decoder by the parallel processing unit for addition comparison selection according to the rate of code and the size of binding field based on this periodicity. And, the feature of the present invention is having the simplicity for hardware and the facility for constitution when constitutes the decoder to the large scale integrated circuit, by constituting data to be able to the series processing, produced from the operation of the unit for parallel addition comparison selection.

### TECHNICAL FIELD

The present invention relates to the method and apparatus, which has improved performance for decoding architecture of multi-level Trellis Coded Modulation (TCM) by using parallel processing technique.

### BACKGROUND ART

Due to the channel impairments such as noise or fading, the error may be occurred in digital data transmission systems. For correcting these errors, the source data had to be encoded by specific method, which is also known as channel coding and then transmitted. This channel coding technique could be partitioned into two categories such as block codes and convolutional codes. Block codes only refer to the current input data whereas convolutional codes refer to past and current data. Block codes take advantage to burst errors but convolutional codes also take advantage to random errors. As near optimum decoding algorithm, the Viterbi algorithm is generally used for decoding convolutional code.

TCM is a modulation scheme combined convolutional codes with the multi-level digital modulation scheme i.e. M-ary Phase Shift Keying (M-PSK) and M-ary Quadrature Modulation (M-QAM). TCM has 3˜6 dB improved coding gain compare with conventional convolutional code. It is also kwon as more effective to the bandwidth or power limited channels. Contemporary digital communication systems, such as High-speed telephone line modems, Digital Television, Asymmetry Digital Subscriber Line (ADSL) modems are its application examples as channel code. But, TCM decoding scheme is more complex for its hardware than conventional convolutional code, because the number of branches increases at each state. For implementing the Viterbi algorithm, the increments of branches cause the increments of Add-Compare-Select (ACS) units. Also, in TCM decoding scheme, a number of branches at each state exponentially increase according to the number of input symbol bits and the constraint lengths. Thus, the large constraint length TCM decoding scheme has a bottleneck in ACS unit and the small constraint length TCM schemes are used in general. In spite of computational reduction algorithm, we have to devised Viterbi decoder architecture for moderate size of computational complexity in TCM decoding scheme.

For the purpose of solving this problem, the Pragmatic TCM (PTCM) decoder architecture (U.S. Pat. No. 5,469,452) was proposed and it operates basically as rate 1/2 or 1/3 conventional convolutional code. When it operates as TCM mode, it is combined rate 2/3 or 3/4 punctured convolutional code with 8-PSK or 16-PSK modulation scheme for increasing the transmission rate. For speed-up the Viterbi decoder, three radix-2 ACS units are used in parallel. But this decoder has a disadvantage of its performance by puncturing and can not applicable to the other modulation scheme such as QAM.

Another treatment of parallel ACS processing is posted on the Korean patent applied No. 0-2000-002/439 and this architecture can divide branches into even and odd states. The number of 2^{m+k} ACS units or multiple number of 2^{m+k} ACS units can process in parallel at each state, where m is number of input symbol bits and k is constraint length. By using the multi-port memory, parallel ACS can access the 2^{m+k} data from current state survivor Path Metric Memory (PMM) and then be processed and write back to the next state PMM in parallel fashion.

But, if the large number of ports is needed, then the shuffle exchange switch causes hardware complexity and slow down the memory speed. Therefore, this method still exist a bottleneck between the multi-port memory and ACS units.

### DISCLOSURE OF INVENTION

The present invention is to devise to solve a complexity of TCM decoder, which can parallel process ACS units using the common periodicity of branches at each state of TCM Viterbi decoder. According to the present invention, branches from current state to next state can divide into common period by the code rate and the constraint length. Therefore, ACS units can process in parallel, which can improve the decoder performance and other peripheral devices process in serial, which can reduce the hardware complexity and offer easy interface with standard DRAM (Dynamic Random Access Memory). A more comprehensive way to obtain of the preferred invention, it can make possible for parallel ACS according to common period of branches at state when code rate is m/(m+1) and constraint length is k. And other peripheral devices of the decoders i.e. path metric memories and survivor path metric memories are operated serially. In a view of VLSI implementation, that is main advantage of the present invention for reducing area and improving performance by the hybrid manner of TCM decoder architecture. Further features and advantages provided by aspects of the present invention will become clear from the following description of embodiments thereof, given by examples and illustrated by the accompanying drawings.

### BRIEF DESCRIPTION OF DRAWINGS

FIG. 1 is a block diagram showing a TCM decoder of the presented invention.

FIG. 2 is a block diagram showing a TCM decoder.

FIG. 3 is a block diagram showing a TCM encoder.

FIG. 4 shows a method of common period construction using radix system.

FIG. 5 is a block diagram showing a TCM encoder with code rate 3/4 and constraint length 5.

FIG. 6 is a block diagram showing a branch metric buffer in ACS.

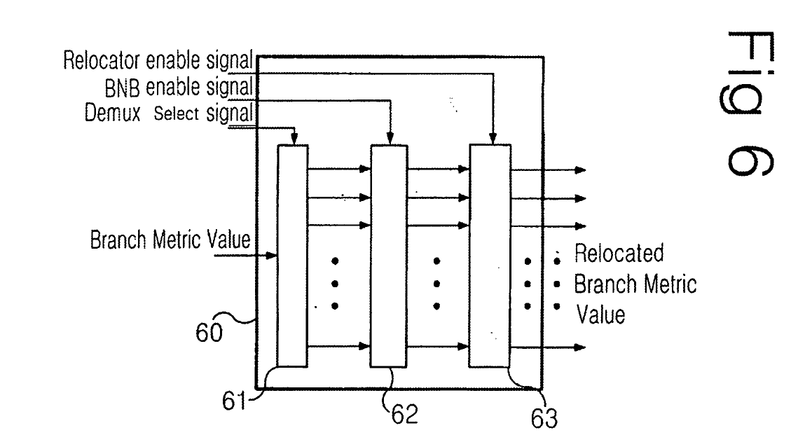

FIG. 7 is a block diagram showing a relocator in branch metric buffer.

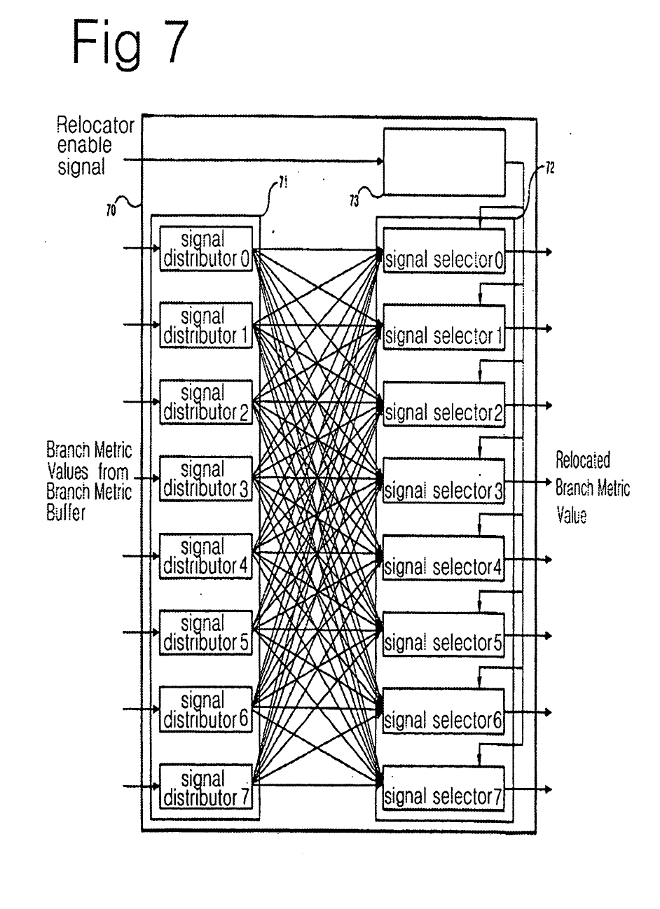

FIG. 8 illustrates a block diagram cooperating with ACS and path metric memory.

FIG. 9 is a block diagram showing single ACS unit.

FIG. 10 is a block diagram showing parallel ACS units.

FIG. 11 illustrates a block diagram cooperating with ACS and path metric memory using single port memory.

FIG. 12 illustrates a block diagram of the trace back memory using single port memory.

FIG. 13 illustrates a block diagram of the minimum search unit using common period of parallel ACS units.

FIG. 14 illustrates a block diagram of the address decoder unit for converting from the temporary location to original address.

FIG. 15 is a block diagram showing a trace back unit.

FIG. 16 is a block diagram showing a demapping unit.

### BEST MODE FOR CARRYING OUT THE INVENTION

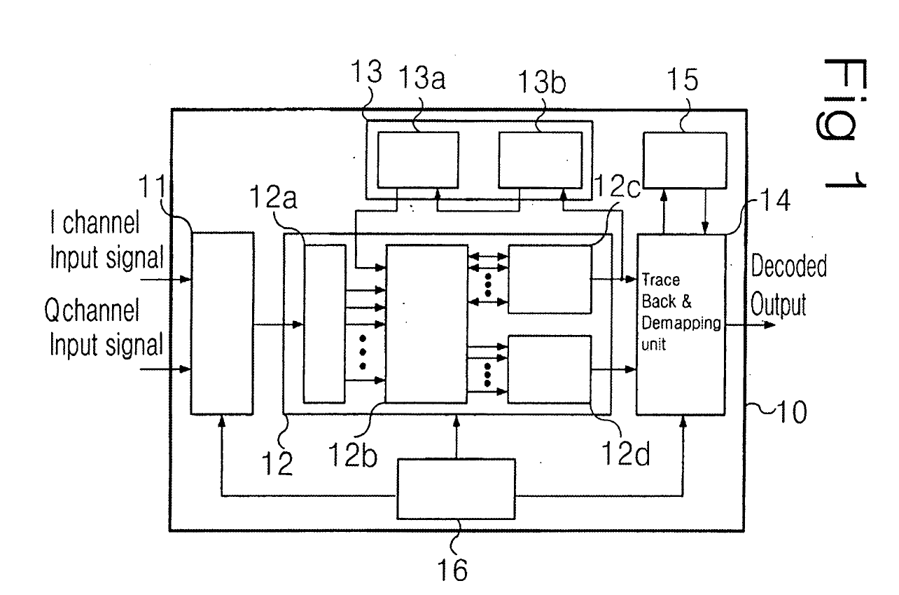

Referring to FIG. 1, a first embodiment of the invention is demonstrated in block diagram form. This embodiment of the present invention provides a TCM decoder (10) whose data is encoded by m bits input to m+1 bits output, further comprising following units;

A Branch Metric Calculator (BMC) (11) computes the Euclidean distances from each code word and received signal, which is contaminated by noise;

A Path Metric Buffer (PMB) (12a) transfers the 2^{m×2(((k-3)/2)-1)} computation results of BMC units (11) to ACS units (12b) in parallel according to common period of Current Path Metric Memory (CPMM);

An ACS unit (12b) adds the 2^{m×2(((k-3)/2)-1)} path metric values, which comes from PMB (12a) and the current path metric value and then be compared with the next path metric values in Next Path Metric Memory (NPMM), and also produces the 2^{m×2(((k-3)/2)-1)} minimum states in parallel by selecting the small paths;

A PMB (12c) stores temporally the minimum state values at each state coming from the ACS unit (12b) and the PMB stored minimum state values are transferred serially to the NPM Memory (NPMM) (13b) during the next state ACS cycles;

A Trace Back Buffer (TBB) (12d) stores the minimum state address information and the transferred serially to the Trace Back Memory (TBM) (15) during the next state ACS cycles;

A Current Path Metric Memory (CPMM) (13a), which is constructed by single port memory or conventional DRAM offers the current metric values to the ACS units (12b);

A Next Path Metric Memory (NPMM) (13b) which is constructed by single port memory stores serially the minimum state value coming from the PMB (12c) and also transfers to the CPMM (13a) after the full completion of ACS cycle at a state;

A Trace Back (TB) unit (14) finds the original code word by demapper function from the minimum state address information in TBM (15), which is a result of trace back operation by starting from the minimum address and also transfers the minimum address, which is converted from minimum value in TBB (12d) to TBM (15);

A Control Unit (16) controls the mentioned above units.

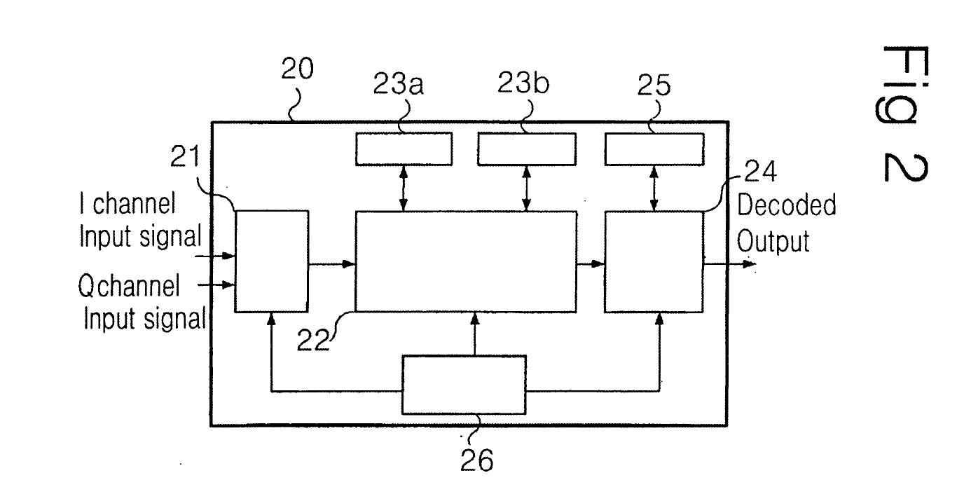

FIG. 2 provides an overview of a TCM decoder (20) as block diagram form, where the input signal denotes the received signals of I (In Phase) and Q (Quadrature Phase) channel, which is contaminated by noise or distorted by channel impairments. A Branch Metric Calculator (21) computes the Euclidian distance between code word and received signal, and this distance measure used for soft decision scheme rather than the Hamming distance measure is used for hard decision scheme in conventional convolutional code. An Add-Compare-Select (ACS) unit (22) adds current path metric value, which comes from the Current Path Metric Memory (CPMM) (23a) and branch metric value computed from BMC (21) and then compare this value with next path metric value, which comes from the Next Path Metric Memory (NPMM) (23b). It selects the small value and it is stored to the Next Path Metric Memory (23b) and the large value eliminated in the survivor path. The Current Path Metric Memory (CPMM) (23a) stores current path metric values and also the next Path Metric Memory (NPMM) (23b) stores next path metric values.

The unit 24 is trace-back and demapping unit, which find the closest path to the minimum state from the accumulated path metric memory of the (23b). By tracing backward in the Trace Back Memory (TBM) (25), it can estimate the minimum state address information and also we can find original transmitted code word by demapping function of unit (24).

The TBM (25) stores state information from ACS (22) and the unit 26 is the control unit, which controls mentioned above units.

The preferred embodiment of the TCM decoder (20) receives I and Q channel signal, which is contaminated by noise. And BMC (21) calculate the Euclidian distance as a branch metric from the received signal to code words. The ACS unit (22) adds the BMC (21) output and current path metric from CPMM (23a) and compares with next path metric in NPMM (23b), and then selects small value. The large values are eliminated in survivor path and also selected values stored in NPMM (23b). Completing ACS operation, there is of no use the current path metric value in CPMM (23a), thus next path metric value in NPMM (23b) is transferred into the CPMM (23a) and NPMM values are set in large value. This causes an automatic transfer CPMM (23a) between NPMM (23b) in next new ACS cycles. The new signal is received, and then these ACS cycles are repeated. An output of ACS unit (22) is the state information, for which is an address of selected path metric value of NPMM (23b), and it is stored into the TBM (25). During the certain periods such as 4˜6 times of a constraint length k, the survivor paths of minimum states are accumulated in TBM (25) and it can estimate the original transmitted code word by trace back and demapping process.

Now, the parallelism of the presented invention to remove the bottleneck of above ACS (22) operation can be explained as follows.

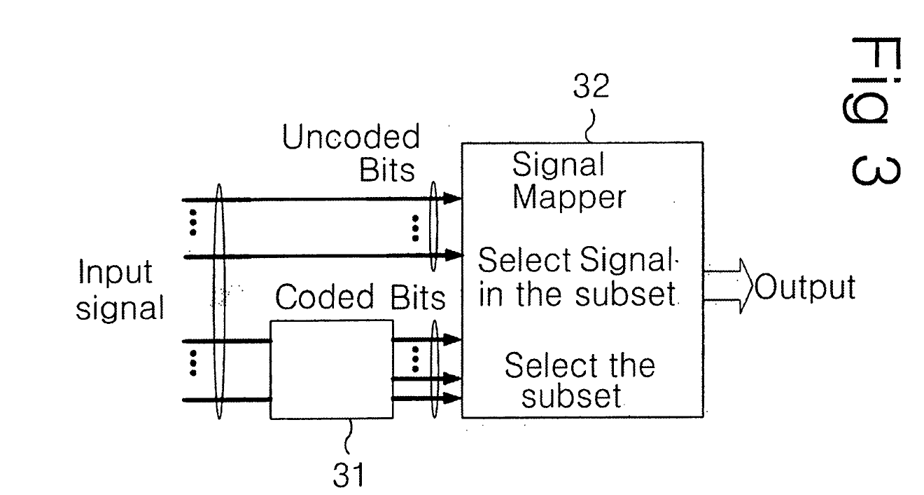

Referring to FIG. 3, it shows a block diagram of TCM encoder. The TCM encoder produces m+1 bits code word by signal mapper using convolutional encoder with rate m/(m+1), whose input is m bits. Thus, it exist 2^{m} possible branches at each state.

If the constraint length is k, then the convolutional encoder holds 2^{(k-1)} states and if the code rate is m/(m+1) then the TCM encoder holds 2^{m+(k-1)} branches totally. At decoding stage, these braches are divided into two categories such as the survivor paths and the eliminated paths. The survivor path, which is the possible branch in minimum state are survived in the Path Metric Memory (PMM) and the other paths are eliminated from the PMM.

The TCM decoder needs total number of 2^{m+(k-1)} ACS operations. For example, if the code rate 3/4 and constraint 7 is chosen, then 2⁽³⁺⁽⁷⁻¹⁾⁾=2048 ACS operation is needed for single symbol decoding. If the single serial ACS unit is used, then it is not possible to process in real time at most applications. Thus, the parallel processing of ACS unit is needed for solving the bottleneck of ACS operations.

In this invention, the 2^{m} branches from the current state to the next state divided into the common period. A current state branches 2^{m} next states. Contrary, a next state comes from 2^{m} current states. This means that 2^{m} current states branch only 2^{m} next states. It said the common period, which is branched to a next common period from the current states, thus the number of common periods could be found the total number of 2^{(k-1)} states divided by 2^{m} branches. In these cases, common periods are mutually independent, and each state is belongs to only one common period. The states in the same common period have the common characteristics i.e. the states in the same common period branch to the same next period. The each state in the next states is grouped into the common period by belonging of the same current state. Thus, the ACS operation can be partitioned into the common period of current states and next states. In the presented invention, the current states denotes a contents of CPMM (23a) and the next states denotes a contents of NPMM (23b)

The states, which is consisted of a common period is depended on input symbol bits m according to the code rate and then the number of states at a symbol period is 2^{m}. Thus the number of common period is 2^{(k-1)}/2^{m}, where k is constraint length and m is input symbol bits. The mentioned above common periods always have radix-2^{m} structure and the periods are mutually exclusive. This means that each common period can be processed with parallel and this is the key concept of the invention.

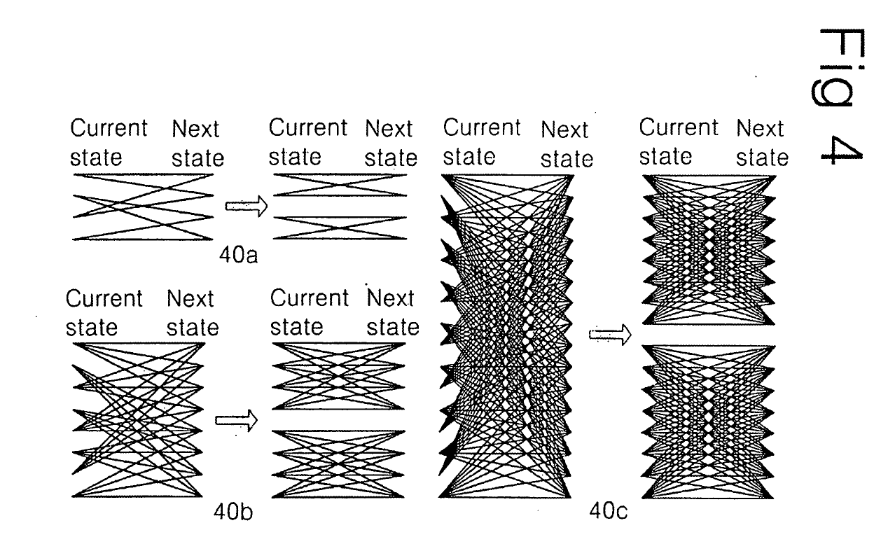

For example, if the code rate is chosen by 1/2, 2/3, 3/4, then the number of states is 2²⁻¹, 2⁴⁻¹, 2⁵⁻¹ respectively and the number of branches is found 2¹, 2², 2³ according to the code rate m. In this case, the all states can divide into the two common periods using above equation that is 2²/2¹=2, 2³/2²=2, 2⁴/2³=2. It is depicted in FIG. 4 as a trellis diagram. FIG. 40a shows radix-2 structure when code rate is 1/2 and constraint length is 3. FIG. 40b illustrates radix-4 structure when code rate is 2/3 and constraint length is 4. FIG. 40c also shows the radix-8 structure when code rate is 3/4 and constraint length is 5.

By using the above property, the ACS operation can be processed with parallel. The 2^{(((k-1)/2)-1)} ACS units is computed with parallel among the 2^{(k-1)}/2^{m} periods. Thus we can generalize above property as follows; the 2^{(((k-3)/2)-1)} ACS unit can process with parallel among the total (2^{m}×2^{(((k-3)/2)-1)}) periods.

For example, if the code rate is 3/4 and constraint length is 5, then the number of branches from current state to next state is 2³=8 and the common periods are 2⁽⁵⁻¹⁾/2³=2. This means that the 2³×2^{(((5-3)/2)-1)}=8 ACS unit can operate with parallel among the 2^{(((5-3)/2)-1)}=1 common periods.

Table 1 shows a common period table of the TCM decoder, which is encoded by parity check polynomials 37, 32, 23, 21 in octal.

TABLE 1

state

| Period | Current State | Next State |
|---|---|---|
| Period 0 | 0, 2, 4, 6, 8, 10, 12, 14 | 0, 1, 2, 3, 4, 5, 6, 7 |
| Period 1 | 1, 3, 5, 7, 9, 11, 13, 15 | 8, 9, 10, 11, 12, 13, 14, 15 |

For another example, if the code rate is 3/4 and constraint length is 7, then the number of branches from current state to next state is 2³=8 and the common periods are 2⁽⁷⁻¹⁾/2³=8. This means that the 2³×2^{(((7-3)/2)-1)}=16 ACS unit can operate among the 2^{(((7-3)/2)-1)}=2 common periods.

Table 2 shows a common period table of the TCM decoder, which is encoded by parity check polynomials 175, 157, 153, 105 in octal.

TABLE 2

| | State | | | |
|---|---|---|---|---|
| | Current State | | Next State | |
| Period | ACS_0 | ACS_1 | ACS_0 | ACS_1 |
| Period 0 | 0, 4, 18, | 1, 5, 19, 23, | 0, 2, 9, 11, | 32, 34, 41, 43, |
| | 22, 42, 46, | 43, 47, 57, 61 | 21, 23, 28, 30 | 53, 55, 60, 62 |
| | 56, 60 | | | |
| Period 1 | 2, 6, 16, 20, | 3, 7, 17, 21, | 1, 3, 8, 10, | 33, 35, 40, 42, |
| | 40, 44, 58, | 41, 45, 59, 63 | 20, 22, 29, 31 | 52, 54, 61, 63 |
| | 62 | | | |
| Period 2 | 8, 12, 26, | 9, 13, 27, 31, | 4, 6, 13, 15, | 36, 38, 45, 47, |
| | 30, 34, 38, | 35, 39, 49, 53 | 17, 19, 24, 26 | 49, 51, 56, 58 |
| | 48, 52 | | | |
| Period 3 | 10, 14, 24, | 11, 15, 25, 29, | 5, 7, 12, 14, | 37, 39, 44, 46, |
| | 28, 32, 36, | 33, 37, 51, 55 | 16, 18, 25, 27 | 48, 50, 47, 59 |
| | 50, 54 | | | |

In Table 1 and 2, current state denotes an address of CPMM (13a) and next state also denotes an address of NPMM (13b).

For efficient implementation of ACS (12), the three additional units such as Branch Metric Buffer (BMB) (12a), Path Metric Buffer (PMB) (12c) and Trace Back Buffer (TBB) (12d) is needed.

The BMB (60) unit temporally stores the branch metric values computed parallel or serial fashion from BMC (11). If the BMC unit operates serially, then branch metric values distribute in BMB (62) unit by using the demux (61). Similarly, if the BMC unit operates in parallel, then branch metric values distribute in BMB (62) unit without demux (61).

The 2^{m}×2^{(((k-3)/2)-1)} branch metric values are transferred to ACS (12b) by BMB (60) and branch locations are relocated by common period of current state. These branch locations are changed by number of states in the period, e.g. 2^{m}. Each periods of current state is relocated same position, thus the relocator (63) distribute branch metric values in the common period as a same fashion.

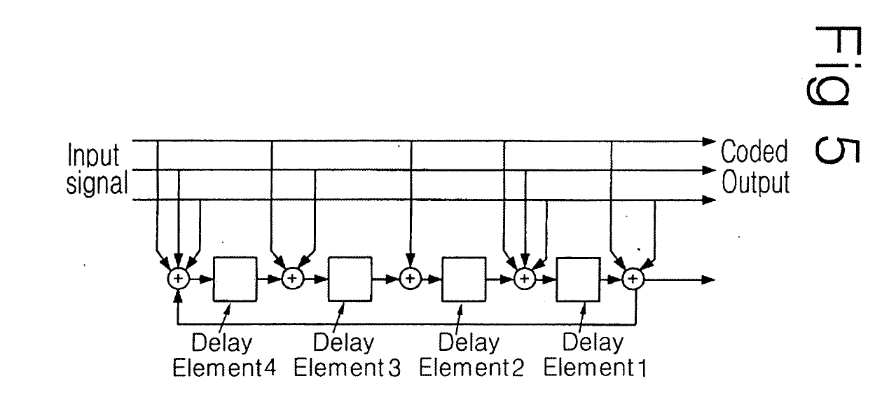

For example, if an encoder is used in FIG. 5 then the relocation table of BMB (12a) is shown in Table 3 for the multi-level TCM decoder. The relocator (70) is consisted of a signal distributor (71), which distribute the signal by using the Table 3 and the 8:1 mux, which select the one of 8 distributed signals.

TABLE 3

| | |
|---|---|
| | Period State |
| Branch | The locations according to the state |

| Location | 0 | 1 | 2 | 3 | 4 | 5 | 6 | 7 |
|---|---|---|---|---|---|---|---|---|
| Branch 0 | 0 | 3 | 6 | 5 | 2 | 1 | 4 | 7 |
| Branch 1 | 1 | 2 | 7 | 4 | 3 | 0 | 5 | 6 |
| Branch 2 | 2 | 1 | 4 | 7 | 0 | 3 | 6 | 5 |
| Branch 3 | 3 | 0 | 5 | 6 | 1 | 2 | 7 | 4 |
| Branch 4 | 4 | 7 | 2 | 1 | 6 | 5 | 0 | 3 |
| Branch 5 | 5 | 6 | 3 | 0 | 7 | 4 | 1 | 2 |
| Branch 6 | 6 | 5 | 0 | 3 | 4 | 7 | 2 | 1 |
| Branch 7 | 7 | 4 | 1 | 2 | 5 | 6 | 3 | 0 |

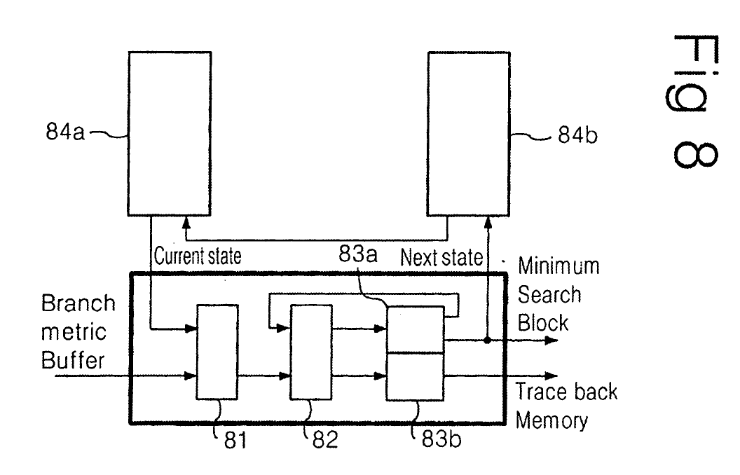

FIG. 8 illustrates a block diagram cooperating with ACS (80) and relocated branch metrics in PMB (70) and other peripheral devices. By the adder (81), Add-Compare-Select (ACS) (80) adds branch metric value, which is relocated by BMB and current path metric value, which comes from the CPMM (84a) and then compare this value with next path metric value, which comes from PMB (83a) substitute the NPMM (84b). It selects the small value and it is stored to the PMB (83a) and also stores state information to the TBB (83b). The Current Path Metric Memory (CPMM) (83a) stores current path metric values and also the next Path Metric Memory (NPMM) (83b) stores next path metric values. Moreover, the state information in the Trace Back Buffer (TBB) (84b) is also saved to the Trace Back Memory in serial. Finally, when all ACS cycles are finished, there is of no use the values of CPMM (84a), thus the CPMM is updated by using the minimum values of NPMM (84b) and prepare for the next ACS cycles.

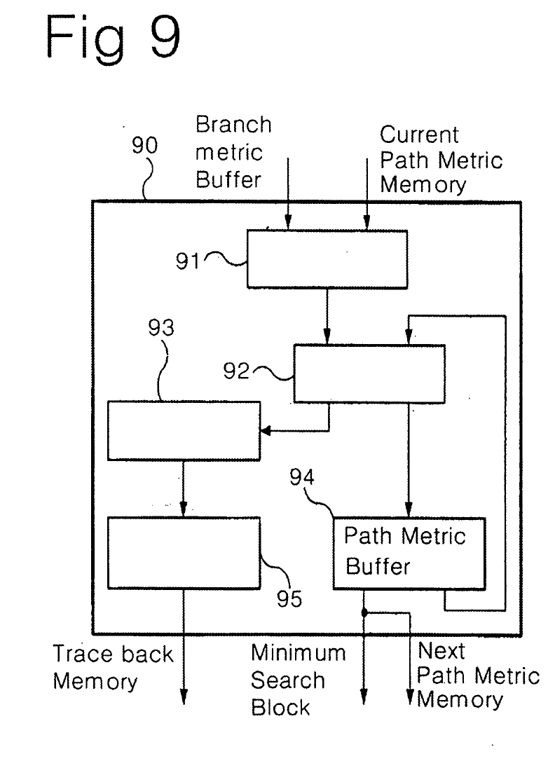

FIG. 9 shows a block diagram of single ACS (90). An Adder (91) adds current metric value with a branch metric value relocated from the BMM and then the compared with next path metric value. The minimum path is selected and computes the state information using State Information Calculator (SIC) (93). The SIC (93) is easily implemented by counters and it is incremented by action of ACS unit. When enable signal is activated, we can calculate location of minimum state rather than minimum state information for trace back. This location of minimum state can be converted into state information and stored into the trace back memory. The selected local minimum value of ACS (92) is stored into the PMB and also feed into the ACS for selecting the next state minimum state. When this process is completed for whole cycle, the minimum value of this cycle is stored to the NPMM and the state information, which is computed by SIC (93) is stored to TBB (95).

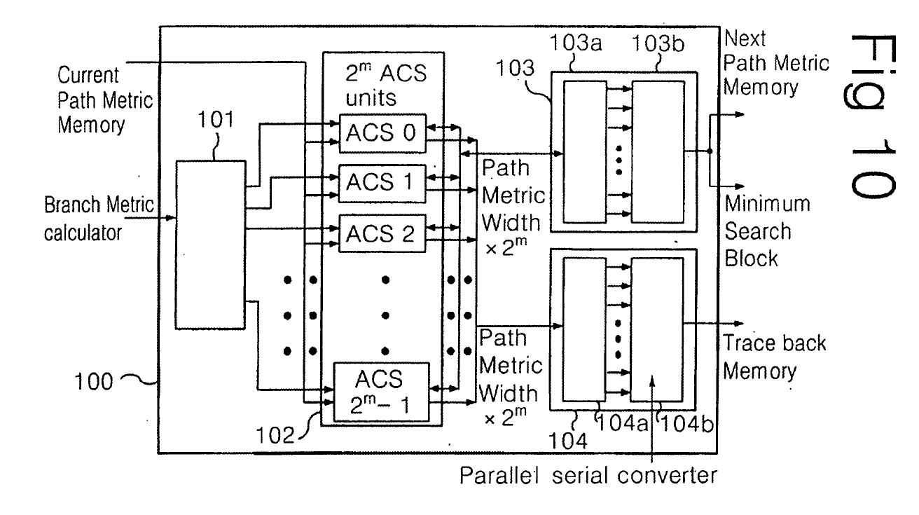

FIG. 10 is a block diagram showing a parallel processing example according to the common period of ACS actions as in FIG. 8.

A Single period is consisted by 2^{m} states, and thus we can construct 2^{m} ACS units (100) in parallel. Firstly, the 2^{m} branch metric values are received in parallel from BMB (101) unit and then added with current state path metric values. Secondly, these values are compared with 2^{m} next state path metric values and selected smaller one. And these selected values are stored into the PMB (103). This action is completed to a single symbol cycle. And it means that we can calculate the minimum state consisting the common period without referring to NPMM unit. The PMB (103) unit stores the minimum state in a single symbol cycle. The minimum state is transferred serially to the NPMM unit and minimum search block in Tack Back (104) unit by using the parallel/serial converter (103b). The TBB (104) unit operates as same PMB (103) with minimum state information rather than minimum state path metric values.

Referring with table 1 and 3, for example, the BMB (101) and ACS (102) is cooperated as following sequence;

Using Table 1, the current branch metric value in 0 of the first common period 0 is added with relocated branch metric values in 0^{th} column of the Table 3. And then compare with next state group of 0, 1, 2, 3, 4, 5, 6, 7 in Table 1 and the selected smaller values are stored to the next state of 0, 1, 2, 3, 4, 5, 6, 7 in PMB (103) unit. If the current state of 0^{th} common period is varied as an order of 2, 4, 6, 8, 10, 12, 14, then the branch metric value is varied as an order of 1, 2, 3, 4, 5, 6, 7. These ordered pair values are added together and compared with next sate path metric values of 0, 1, 2, 3, 4, 5, 6, 7 and the selected smaller one is restored to the PMB as a same order. If the ACS actions in all states of a single symbol period are completed, then this parallel ACS is completed. Other symbol periods are repeated with same operation.

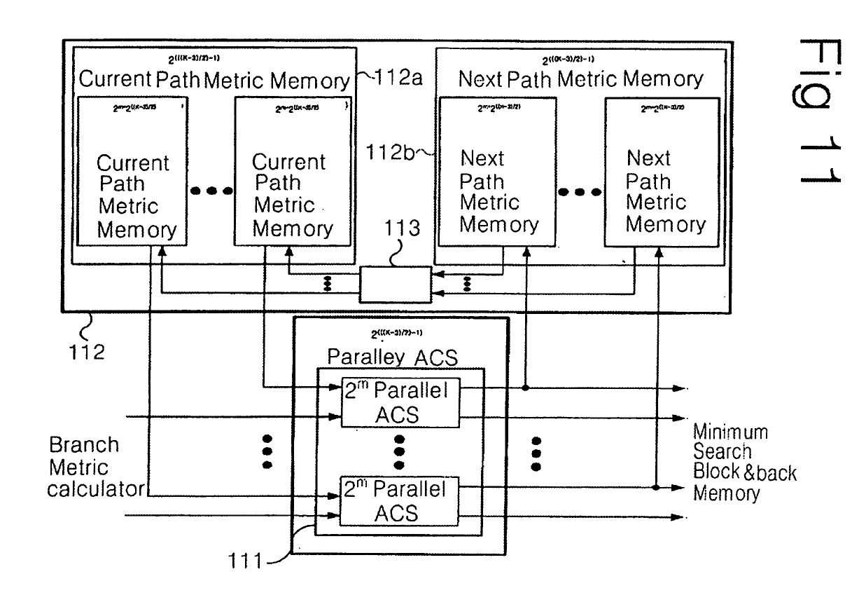

FIG. 11 illustrates block diagram of the parallel ACS (111) (e.g. 2^{m}×2^{(((k-3)/2)-1)} states) cooperating with the PMB (112). The PMB stores minimum states in single symbol cycle and serially transfers to the single port memory during the ACS operations of the next symbol period by using the parallel/serial converter. The state values of PMB (112) are transferred in serial to the Current-state Path Metric Memory (CPMM) and it is used updating the CPMM. Thus, PMM (112) is stores 2^{m}×2^{((k-3)/2)} states in single port memory. Transferring minimum state values in PMB (112a) to the CPMM (111b) throughout the switch (113), the address in single port memory is generated by address generator and controlled by Control Unit (16). This design method could reduce the hardware area for constructing with single port RAM in the PMM (112) and also minimize the I/O delay of the PMM (112) for block access with ACS (111) in FIG. 11.

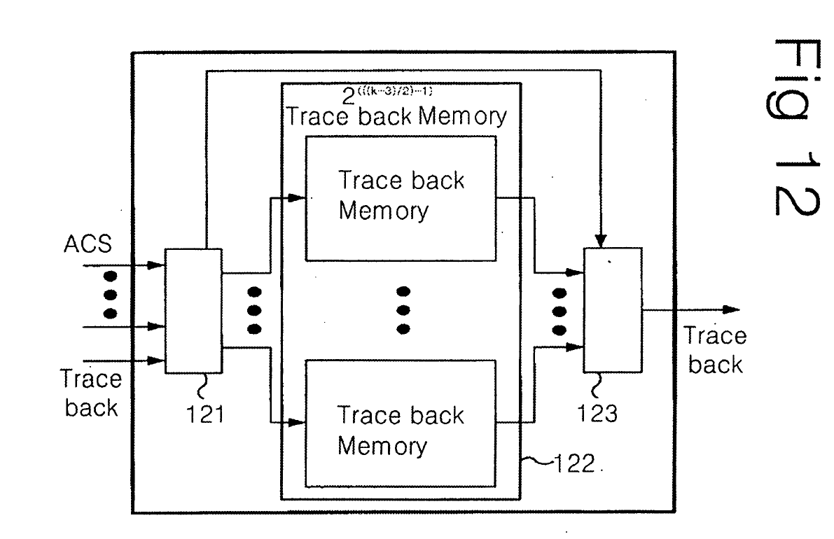

Similarly, a Trace Back Memory (TBM) (120) in FIG. 12 is constructed with the single port memory and the TBB (12d), for which is interfaced with parallel/serial converter. The 2^{(((k-3)/2)-1)} minimum states information in TBB (12d) are serially transferred to the TBM (122). This method is minimized the number of memory access and also stores continuously without interruption, where the switch (121) transfers state information coming from ACS. And the Trace Back Memory (TBM) (122) with size of trace-back depth X number of states X data width is divided into the 2^{(((k-3)/2)-1)} blocks. The selector (123) selects the data from trace back memory (122) and transfers to trace back unit.

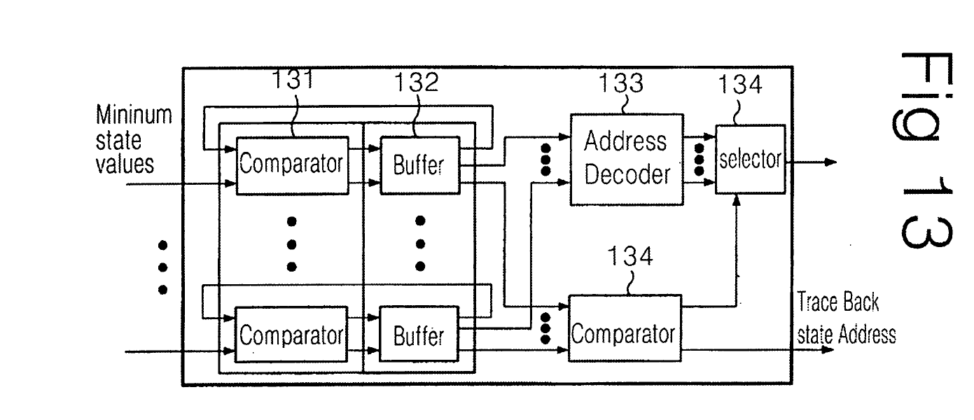

FIG. 13 is a block diagram showing a minimum search block, which is searching the minimum state for start address of trace back. A cycle based serial search for 2^{(((k-3)/2)-1)} minimum values is used during the next ACS cycle.

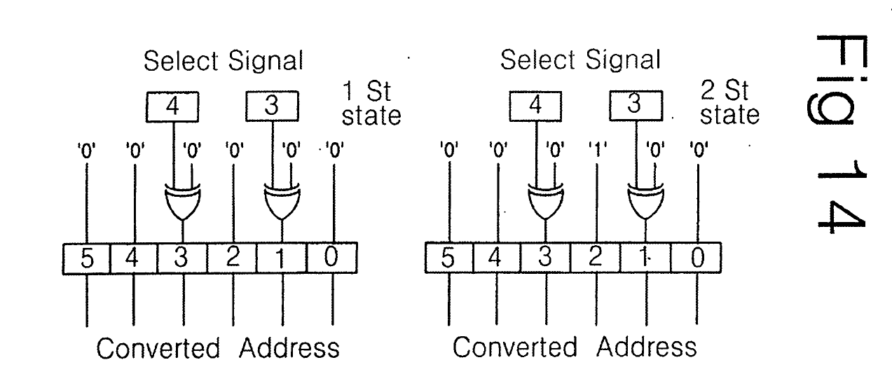

FIG. 14 is a schematic diagram showing an address decoder, which generates the trace back address from the trace back buffer (12d) in a common period. The state information in the trace back buffer is only location information using counter, therefore, the address decoder for location information is needed and it convert the location information to the state address information. In minimum search block (120), it also searches the computation order. Thus, an address decoder is used for converting original state address and this also used to start address in trace back operation. This address decoder is easily implemented by hardwired logic, because the order of common period can prepare referring to Table 1 and Table 2.

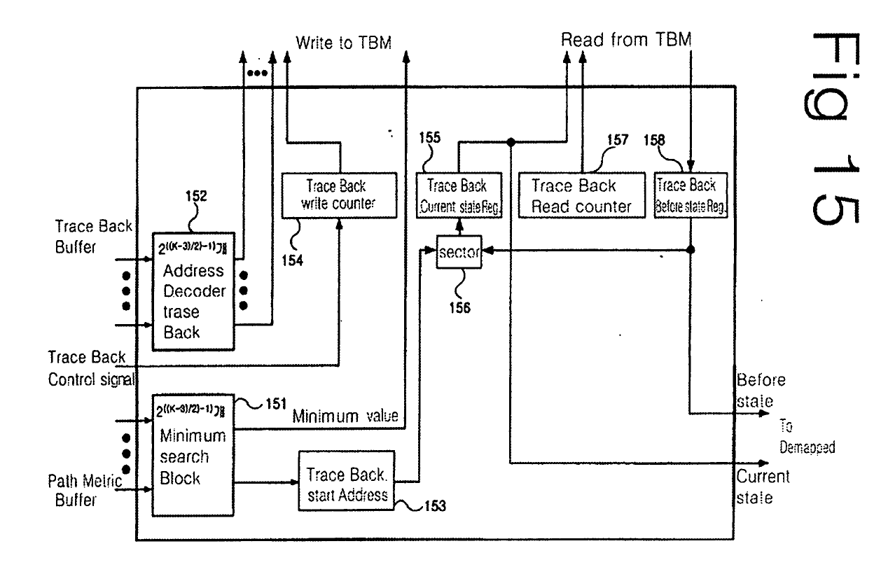

FIG. 15 is a block diagram showing a trace back operation. The Trace Back Memory (TBM) accumulates the minimum values searched by minimum searching block (151) in 4˜6 times of constraint length k so called trace back depth. By using the trace back operation, we can estimate the current minimum state and before state. Form the estimated current minimum state and before state information, it could be decoded the original output code by demapping process.

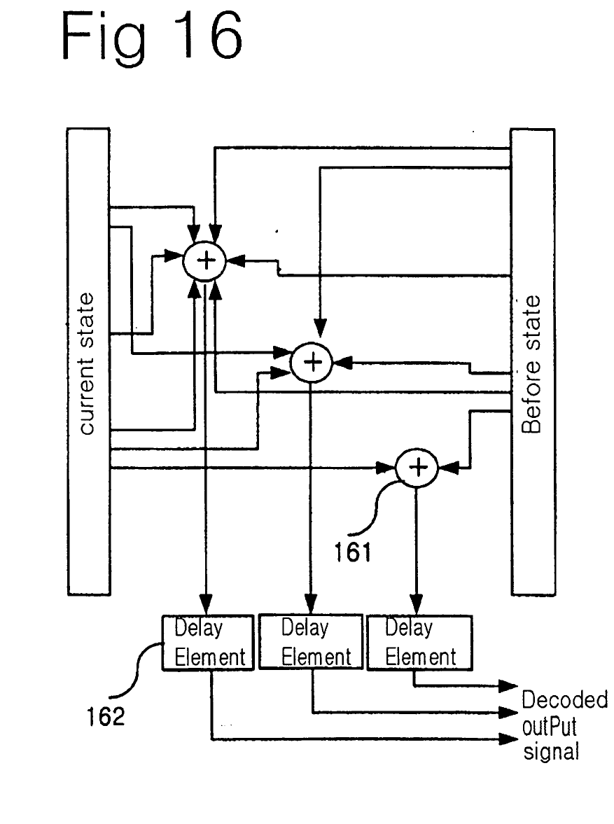

A demapper unit for decoding an output code is illustrated in FIG. 16 as a schematic diagram and it decodes original code from current and before state information by using the Exclusive-OR gates (161). The control unit (16) generates simultaneously control signals and addresses of the memories. The each address can be pre-computed referring table, thus the demapper can be implemented by hardwired logic like address decoder (140).

Mentioned above examples with certain constraint length and code rate is not to restrict the present invention but help to understand the co-operations between the devices. Although the present invention has been described in detail, it should be understood that various changes and substitution and alternation could be made thereto without departing from the sprit and scope of the invention as defined by the appended claims.

Summarizing the individual describes, the present invention is related to the decoding method and apparatus of multi-level TCM decoder where constraint length is k and code rate is m/(m+1), for which has improved performance throughout the parallel processing techniques. In the present invention, the branches from the current state to the next state could divide into 2^{(k-1)}/2^{m} categories named common period according to the code rate and constraint length. The 2^{(((k-3)/2)-1)} ACS make possible parallel process and 2^{(((k-3)/2)-1)} wide single port RAM can be used for path metric memory and trace back memory. The parallel ACS units in the common period is relocated its position in path metric buffer and branch metric buffer and then minimum values and minimum states information are transferred to PMM and TBM in serial fashion completing before the ACS operation. The Trace Back unit searches start address of the trace back operation by using the 2^{(((k-3)/2)-1)} minimum search block, address decoder in the TB unit transforms its address form the location information in the ACS and PMB. All addresses in decoder supplied by control unit.

### Industrial Applicability

A method and apparatus of the present invention could parallel process the ACS unit according to the common period of branches from current state to next state by constraint length and code rate. The parallel 2^{(((k-3)/2)-1)} ACS results are also stored in serially to the RAM. Thus, main advantage of the present invention is concluded that it can obtain the improved decoder performance by parallel processing and the area efficient implementation is make possible with the VLSI and standard RAM.

What is claimed is:

1. A multi level TCM decoder architecture with m bits input and m+1 bits outputs, further comprising;
a 2^{(k-1)}/2^{m} ACS (12) unit for accompanying common periods of branches according to code rate and constraint length can process in parallel;
a serial interface method comprising RAM and parallel 2^{m}×2^{(((k-3)/2)-1)} or 2^{(((k-3)/2)-1)} ACS;
a decoding method above featured parallel ACS and serial RAM comprising as the follows.

2. The construction method of common period, as set forth in claim 1, further comprising Radix-2^{m} parallel ACS according to the common period of branched from the current state to next state.

3. An ACS unit (12), as set forth in claim 1, comprising branch metric buffer (12a), which relocates 2^{m}×2^{(((k-3)/2)-1)} branch metric values in the CPMM (13a) and transfers parallel to the ACS unit;
the parallel ACS unit (12b) adding branch metric value from BMC and current metric values from PMM and then selects the small one, which produces 2^{m}×2^{(((k-3)/2)-1)} states information and minimum values in parallel;
a Path Metric Memory (12c) stores minimum states information during the ACS and holding minimum states information feed serially into the NPMM (13b) in a next ACS cycle.

4. A BMB (12a), as set forth in claim 3, is a buffer memory (62), which stores branch metric values computed from BMC (11) serial or parallel fashion;
in serial case, a demux (61) distributes branch metric values to BMB;
in parallel case, A BMB (62) is not use demux (61);
a relocator (63) changes its location according to the current states stored in BMB and 2^{m}×2^{(((k-3)/2)-1)} branch metric values are transferred to ACS unit using the relocator in parallel manner.

5. A BMB (60), as set forth in claim 4, further comprising;
a signal distributor, which distribute the 2^{m} signals according to relocation table;
a 2^{m}:1 demux, which select one signal according to the period table of the relocation.

6. A parallel ACS unit (12b), as set forth in claim 3, further comprising;
a BMC (102) receives and stores the 2^{m}×2^{(((k-3)/2)-1} branch metric values from relocated values in BMB (101) using relocation table;
an adder, which adds a current state value and branch metric value;
a comparator, which compare adder output and next state path metric values;
a selector, which selects the small one by the comparator output.
a parallel ACS unit (12b) which can produce a minimum value without referring a NPMM.

7. A parallel ACS unit (90), as set forth in claim 6, further comprising;
the adders (91), which add relocated branch metric values in BMB (12a) and current metric values;
the compares and selectors, which compare adder outputs and next state values and decide the minimum state and then the state information are used for state information calculator (93);
a state information calculator (93) consisting with counter, which is increased by 1, if ACS operation is activated;
a state information calculator (93), which can calculate the minimum state information using the location information for trace back operation.

8. A PMB (12c), as set forth in claim 3, further comprising;
a buffer (103a), which stores minimum value;
a parallel/serial converter, which transfers minimum value to minimum search block and next path metric memory in serial.

9. A TBB (12d), as set forth in claim 3, further comprising;
a buffer (103a), which stores minimum state information;
a parallel/serial converter, which transfers minimum state information to trace back memory.

10. A PMM (13) and TBM (15), as set forth in claim 1, further comprising;
a single port memory coupled with PMB(12c) and TBB(12d);
a parallel/serial converter coupled with 2^{(((k-3)/2)-1)} single port memory.

11. A PMM (13), as set forth in claim 10, further comprising;
a 2^{(((k-3)/2)-1)} wide single port memory, which can stores local minimum values at all states coupled with parallel/serial converter;
a NPMM (112b) holds the local minimum values at next state;
a selector switch (113), which can select one of 2^{m}×2^{(((k-3)/2)} possible values.

12. A TBM (15), as set forth in claim 10, further comprising;
a TBB (12d) coupled with parallel/serial converter;
a switch (121) coupled TBM (122), which is stored minimum state information to TBM (122);
a TBM (122), which constructed by single port memory, with a size of trace back depth×number of states×data width;
a selector (123) coupled with a TBB (12d).

13. A multi level TCM decoder architecture with constraint length k and m bits input and m+1 bits outputs, further comprising;
a Trace Back (TB) (14) coupled TBB(12d), which stores minimum state information;
a address decoder (140), which convert location information in TBB(12d) into the state information;
a TB (14) unit, which accumulate minimum values as 4˜6 times of trace back depth and then retrace the minimum state coming from before state;
a demapper coupled demapping function in hardwired logic from a table.

14. A address decoder (133), as set forth in claim 13, which is consisted of exclusive-or gates in hardwired logic using a pre-computed table.

15. A minimum search block (140), as set forth in claim 13, which can search the minimum values in next path metric values of 2^{(((k-3)/2)-1)} from NPMM (13b) and it is not need extra time that because the parallel 2^{(((k-3)/2)-1)} block can process independent with the ACS cycle.

16. A demapping (161) unit, as set forth in claim 13, further comprising;
the exclusive-or gates, which can decode original output from current state and before state information.
